(19) United States
(12) Patent Application Publication
(10) Pub. No.: US 2023/0179198 A1
(43) Pub. Date: Jun. 8, 2023

(54) METHOD FOR OPERATING A SILICON CARBIDE (SIC) MOSFET ARRANGEMENT AND DEVICE

(71) Applicant: Robert Bosch GmbH, Stuttgart (DE)

(72) Inventor: Jonathan Winkler, Sonnenbuehl (DE)

(21) Appl. No.: 17/911,868

(22) PCT Filed: May 7, 2021
(86) PCT No.: PCT/DE2021/100417

§ 371 Date: Sep. 15, 2022

(30) Foreign Application Priority Data
May 8, 2020 (DE) 10 2020 205 797.4

(51) Int. Cl. H03K 17/12; H03K 17/0812; H01L 29/16

(52) U.S. Cl. CPC H03K 17/122; H03K 17/08122; H01L 29/1608

(57) ABSTRACT

A method for operating a silicon carbide (SiC) MOSFET arrangement, The arrangement includes two or more SiC MOSFETs, which are set up such that they are connected electrically in parallel with one another, and is arranged in a device. The method comprises the step of switching on the SiC MOSFETs while avoiding overloading individual ones of the SiC MOSFETs. A device is also described which includes a SiC MOSFET arrangement that includes two or more SiC MOSFETs, which are set up such that they are connected electrically in parallel with one another, and a switch unit that is set up for switching the SiC MOSFET arrangement. The switch unit is set up for switching on the SiC MOSFETs while avoiding overloading individual ones of the SiC MOSFETs.

### FIELD

The present invention relates to a method for operating a silicon carbide (SiC) MOSFET arrangement that includes two or more SiC MOSFETs, which are set up such that they are connected electrically in parallel with one another, and is arranged in a device, and to a device which includes a SiC MOSFET arrangement that includes two or more SiC MOSFETs, which are set up such that they are connected electrically in parallel with one another, and a switch unit that is set up for switching the SiC MOSFET arrangement.

### BACKGROUND INFORMATION

Methods and devices of the general types mentioned above are generally available. A MOSFET is a metal-oxide semiconductor field-effect transistor. It includes an insulated gate terminal, which serves as a control connector, a drain terminal, and a source terminal. If a gate source voltage is applied, it becomes possible to modify a resistance between the drain terminal and the source terminal in order to switch the transistor between a blocked state and a conductive state between the drain and the source terminals.

In order to avoid PTO (parasitic turn-on), SiC MOSFETs are switched off by way of a negative switch-off voltage at the gate terminal. While the negative switch-off voltage applies at the gate terminal, the SiC MOSFET is in the accumulation phase—that is, as a result of an electrical field, positive charge carriers migrate to the interface between the body region and the gate. Because of the only moderate quality of the oxide and the resulting holes, which form energy levels within the bandgap, the positive charges may temporarily have the energy levels of the holes, as a result of the accumulation. They remain there for a certain time, with the result that the threshold voltage of the MOSFET, or the switch-on resistance, changes. Because the period for which the holes remain charged is limited and they are compensated by electrons at the time of switching on the MOSFET, the change in the threshold voltage or switch-on resistance is variable dynamically or over time. This behavior is known as hysteresis of the threshold voltage. This effect does not occur in a silicon MOSFET.

The more negative the applied switch-off voltage during accumulation, the greater the effect. This takes the form of a current surge when a SiC MOSFET is switched on, resulting from different negative switch-off voltages. The current surge subsides because the captured positive charges are compensated by negative charges during switch-on. The behavior corresponds to a briefly lower switch-on resistance which can be adjusted by the switch-off voltage (negative voltage).

A problem which may arise in SiC MOSFET arrangements and may in particular be dependent on the operating method may be a short service life of the SiC MOSFETs. As a result of electrical asymmetry, the load on individual MOSFETs in relation to other MOSFETs that are connected in parallel may be drastically increased. This has an adverse effect on the service life of the MOSFETs.

### SUMMARY

A method according to the present invention, for operating a SiC MOSFET arrangement that includes two or more SiC MOSFETs, which are set up such that they are connected electrically in parallel with one another, and is arranged in a device is provided. According to an example embodiment of the present invention, the method includes the following step:

Switching on the SiC MOSFETs while avoiding overloading individual ones of the SiC MOSFETs.

The method according to the present invention has the advantage that the service life of the SiC MOSFET arrangement is extended because the operating method ensures that the individual SiC MOSFETs are not overloaded at the time of switching on. Thus, simple extension of the service life may be ensured by a suitable method, presented here, for operating the SiC MOSFET arrangement.

According to an example embodiment of the present invention, preferably, the method comprises the step of balancing out differences in a switch-on resistance between the SiC MOSFETs in order to avoid overload at the time of switching on. If the differences are balanced out, then at the time of switching on an at least similar current flow through the SiC MOSFETs can be ensured, with the result that overloading individual ones of the SiC MOSFETs is avoided. However, it is particularly preferable for the respective switch-on resistances to be balanced out such that the current flow through the SiC MOSFETs at the time of switching on is identical for each SiC MOSFET. In that case, all the SiC MOSFETs in the arrangement are advantageously under the same load, and overloading of individual ones of the SiC MOSFETs is thus avoided.

According to an example embodiment of the present invention, it is preferred if the method includes switching off each SiC MOSFET at a respectively established negative switch-off voltage that differs from the negative switch-off voltage of the other SiC MOSFETs, in order to avoid overload at the time of subsequently switching on the SiC MOSFETs. Thus, each SiC MOSFET in the parallel arrangement is preferably switched off at an individual negative switch-off voltage. This can prevent overloading of individual ones of the SiC MOSFETs as a result of current surges at the time of subsequently switching on. Within the context of the present invention, a negative switch-off voltage is understood to be a switch-off voltage of less than zero volts—that is to say having a negative sign. A large negative switch-off voltage is, relatively speaking, further away from zero volts than a small negative switch-off voltage—that is to say that it has larger value in numerical terms. For example, −12 volts is a larger negative switch-off voltage than −4 volts.

Some specific embodiments of the present invention provide for the respective negative switch-off voltage to be established depending on a threshold voltage of the respective SiC MOSFET. As a result, for a successive switch-on procedure it is possible to briefly balance out differences in the threshold voltage/switch-on resistance. It may be particularly advantageous to take the threshold voltage or the switch-on resistance as a basis when allocating the respective negative switch-off voltage, since the SiC MOSFET with the lowest threshold voltage would always switch on first and thus would be subject to a high current load whenever the SiC MOSFET arrangement was switched on. This SiC MOSFET would then be particularly subject to wear and might have a reduced service life. If two or more SiC MOSFETs have the same threshold voltage, then the same negative switch-off voltage may be established for these SiC MOSFETs.

According to an example embodiment of the present invention, preferably, the method includes establishing the respective negative switch-off voltage such that a decreasing switch-off voltage is allocated to the SiC MOSFETs in the order of their increasing threshold voltage. Preferably, the more negative the switch-off voltage, the earlier the SiC MOSFET switches on. As the gate voltage increases, it is possible for example for a switching threshold of approximately 13 mA, for a switch-off voltage of −12 V, already to be reached at approximately 3.8 V, whereas the threshold current for −4 V is only reached at approximately 4.4 V. SiC MOSFETs having a low threshold voltage at switch-on are preferably operated with as small as possible a negative switch-off voltage at the time of switch-off. This means that the negative switch-off voltage for these SiC MOSFETs may be a negative value relatively close to zero volts. By contrast, SiC MOSFETs having a comparatively high threshold voltage at switch-on are preferably operated with, in relative terms, as high as possible a negative switch-off voltage at the time of switch-off. This means that the negative switch-off voltage in such SiC MOSFETs may be a negative value relatively further away from zero volts. In other words, SiC MOSFETs having a low threshold voltage are preferably operated at as high as possible a switch-off voltage (close to zero), and SiC MOSFETs having a high threshold voltage are preferably operated at as negative as possible a switch-off voltage. In this way, the switch-on resistances between the SiC MOSFETs of the arrangement may be matched to one another and thus the differences in the switch-on resistance balanced out.

In the absence of utilizing the effect of hysteresis of the threshold voltage in SiC MOSFETs, a similar behavior could be achieved by (temporarily) increasing the positive switch-on voltage at the MOSFET gate.

In some specific embodiments of the present invention, electrically symmetrical switching on of the SiC MOSFETs is provided, preferably after switching off. The present invention can thus exploit a property of the SiC MOSFET in order to switch on symmetrically a plurality of semiconductors that are connected in parallel and have different threshold voltages and switch-on resistances. This produces an electrically symmetrical switching on, as a result of which overloading individual switches at the time of switching on is avoided. This is because, if one switch—that is to say one SiC MOSFET-switches on sooner than the others, it briefly carries a large proportion of the current.

It is preferable if operation of the SiC MOSFET arrangement is performed by a switch unit. Such switch units are conventional to those skilled in the art. They may be in particular microchips, programmed control units and similar components frequently used in this technical sector.

Further, according to the present invention, a device is provided which includes a SiC MOSFET arrangement that includes two or more SiC MOSFETs, which are set up such that they are connected electrically in parallel with one another, and a switch unit that is set up for switching the SiC MOSFET arrangement, the switch unit being set up for switching on the SiC MOSFETs while avoiding overloading individual ones of the SiC MOSFETs.

A device according to the present invention may have the advantage that the service life of the SiC MOSFET arrangement is extended because the operating method ensures that the individual SiC MOSFETs are not overloaded at the time of switching on. Thus, simple extension of the service life may be ensured by the suitable device presented here. A further advantage results from greater efficiency of the device according to the present invention.

According to an example embodiment of the present invention, it is preferred if the switch unit is set up to switch off each SiC MOSFET at a respectively established negative switch-off voltage that differs from the voltage of the other SiC MOSFETs, in order to avoid overload at the time of subsequently switching on by the switch unit. Thus, each SiC MOSFET in the parallel arrangement is preferably switched off at an individual negative voltage. This can prevent overloading individual ones of the SiC MOSFETs as a result of current surges at the time of switching on.

In specific embodiments of the present invention, it is provided for the switch unit to be set up to switch the SiC MOSFETs on electrically symmetrically, preferably after switching off. The present invention can thus exploit a property of the SiC MOSFET in order to switch on symmetrically a plurality of semiconductors that are connected in parallel and have different threshold voltages and switch-on resistances. This produces an electrically symmetrical switching on, as a result of which overloading individual switches at the time of switching on is avoided. This is because, if one switch—that is to say one SiC MOSFET—switches on sooner than the others, it briefly carries a large proportion of the current.

It is particularly preferable if the switch unit is set up to perform a method, described above, for operating a SiC MOSFET arrangement in one of the described embodiments. Details on this and the resulting advantages were already described above, so there will be no repetition of these here. For example, the switch unit may be set up to perform the method with the aid of a computer program, in particular if the switch unit is a microchip or a programmed control unit.

Advantageous developments of the present invention are disclosed herein.

### BRIEF DESCRIPTION OF THE DRAWINGS

Specific exemplary embodiments of the present invention are explained in more detail with reference to the figures and the description below.

FIG. 1 shows a device according to a first example embodiment of the present invention.

FIG. 2 shows a method according to the first example embodiment of the present invention.

### DETAILED DESCRIPTION OF EXAMPLE EMBODIMENTS

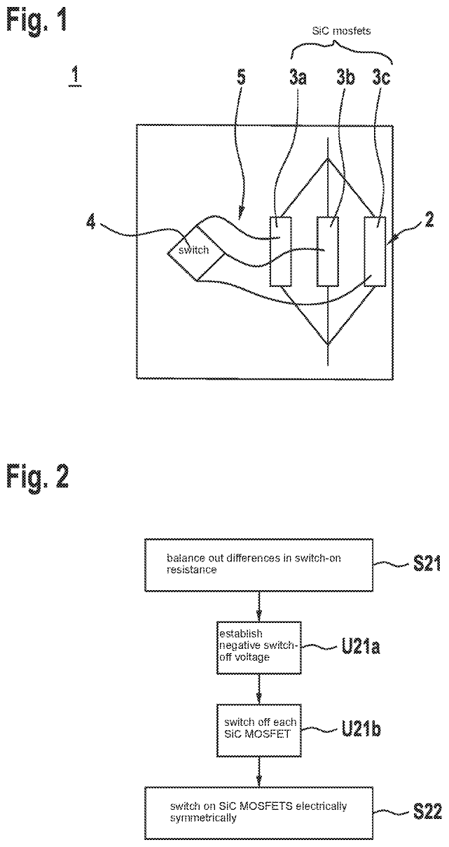

FIG. 1 shows a device 1 that includes a silicon carbide (SiC) MOSFET arrangement 2 that includes two or more SiC MOSFETs 3a, 3b, 3c, which are set up such that they are connected electrically in parallel with one another, and a switch unit 4 that is set up for switching SiC MOSFET arrangement 2. Switch unit 4 is a programmed control unit, which is connected by way of a respective electrical connection 5 to each of SiC MOSFETs 3a, 3b, 3c at their respective gate terminal (not shown) in order to switch SiC MOSFET arrangement 2. Here, SiC MOSFET arrangement 2 comprises, by way of example, three SiC MOSFETs 3a, 3b, 3c connected in parallel, but in other embodiments only two or indeed more than three SiC MOSFETs 3a, 3b, 3c are provided. For the sake of simplifying the illustration, details of the circuit in which SiC MOSFET arrangement 2 is contained are not presented in more detail, since the present invention relates to operation of SiC MOSFET arrangement 2, and in principle can be used in any device 1 in which such SiC MOSFETs 3a, 3b, 3c connected in parallel with one another are utilized. Here, device 1 is a converter (such as an inverter for electrical drives).

Switch unit 4 is set up to switch on SiC MOSFETs 3a, 3b, 3c while avoiding overloading individual ones of SiC MOSFETs 3a, 3b, 3c, as explained below. For this purpose, switch unit 4 is set up to switch off each SiC MOSFET 3a, 3b, 3c at a respectively established negative switch-off voltage that differs from the voltage of the other SiC MOSFETs 3a, 3b, 3c, in order to avoid overload at the time of subsequently switching on by switch unit 4. Further, switch unit 4 is set up to switch SiC MOSFETs 3a, 3b, 3c on electrically symmetrically after switching off.

FIG. 2 shows a specific embodiment of a method for operating a silicon carbide (SiC) MOSFET arrangement 2 that includes two or more SiC MOSFETs 3a, 3b, 3c that are set up such that they are connected electrically in parallel with one another. Switch unit 4 in FIG. 1 is set up to perform the illustrated method.

In a step S21, differences in a switch-on resistance between SiC MOSFETs 3a, 3b, 3c are balanced out in order to avoid overload at the time of switching on. In a first sub-step U21a of step S21, a respective negative switch-off voltage is established depending on a threshold voltage of the respective SiC MOSFET 3a, 3b, 3c. This establishing may be performed by determining the respective threshold voltage and, depending on this, programming control unit 4 accordingly. Here, the respective switch-off voltage is established such that a decreasing switch-off voltage—that is to say a switch-off voltage of less than zero volts, increasing in numerical terms—is allocated to SiC MOSFETs 3a, 3b, 3c in the order of their increasing threshold voltage. This means that the greater the threshold voltage or switch-on resistance of a SiC MOSFET 3a, 3b, 3c, the lower—that is to say the further away from zero and the larger in numerical terms—the negative switch-off voltage selected. In a table in switch unit 4, there would then be allocated to the SiC MOSFET 3a, 3b, 3c with the highest threshold voltage the negative switch-off voltage that is largest in numerical terms—that is to say the negative switch-off voltage furthest away from zero. By contrast, the smallest negative switch-off voltage in numerical terms—that is to say the negative switch-off voltage closest to zero—would be allocated to the SiC MOSFET 3a, 3b, 3c with the lowest threshold voltage. The other SiC MOSFETs 3a, 3b, 3c would be fit into the table between these two extreme values, in the order of their threshold voltage. In the present example from FIG. 1, the left-hand SiC MOSFET 3a has the highest threshold voltage, and switch unit 4 allocates to it the highest negative switch-off voltage—that is to say the negative switch-off voltage with the highest numerical value. The right-hand SiC MOSFET 3c has the lowest threshold voltage, and switch unit 4 allocates to it the lowest negative switch-off voltage, which lies closer to zero than that of the left-hand SiC MOSFET 3a. The middle SiC MOSFET 3b has a threshold voltage between the other two SiC MOSFETs 3a, 3c, and so switch unit 4 also allocates to the middle SiC MOSFET 3b an individual negative switch-off voltage, which lies between those of the other two SiC MOSFETs 3a, 3c.

In a second sub-step U21b of step S21, each SiC MOSFET 3a, 3b, 3c is switched off at the respectively established negative switch-off voltage, which differs from the negative switch-off voltage of the other SiC MOSFETs 3a, 3b, 3c, in order to avoid overload at the time of subsequently switching on SiC MOSFETs 3a, 3b, 3c.

Then, in a step S22, SiC MOSFETs 3a, 3b, 3c are switched on electrically symmetrically by switch unit 4, and thus SiC MOSFETs 3a, 3b, 3c are switched on while avoiding overloading individual ones of the SiC MOSFETs 3a, 3b, 3c. As a result of the previous adaptation of the respective negative switch-off voltages to the individual switch-on resistances of SiC MOSFETs 3a, 3b, 3c in step S21, switching on is performed electrically symmetrically.

As illustrated by FIGS. 1 and 2, the present invention thus exploits a property of SiC MOSFET 3a, 3b, 3c in order to be able to switch on symmetrically a plurality of semiconductors—that is to say, SiC MOSFETs 3a, 3b, 3c—connected in parallel and having different threshold voltages and switch-on resistances. Thus, the service life of SiC MOSFETs 3a, 3b, 3c can be extended in a simple manner, since overloading of individual SiC MOSFETs 3a, 3b, 3c at the time of switching on is avoided.

1-10. (canceled)

11. A method for operating a silicon carbide (SiC) MOSFET arrangement that includes two or more SiC MOSFETs which are connected electrically in parallel with one another, and arranged in a device, the method comprising:
switching on the SiC MOSFETs while avoiding overloading individual ones of the SiC MOSFETs.

12. The method as recited in claim 11, further comprising:
balancing out differences in a switch-on resistance between the SiC MOSFETs to avoid overload at a time of switching on.

13. The method as recited in claim 11, further comprising:
switching off each of the SiC MOSFETs at a respective established negative switch-off voltage that differs from a respective established negative switch-off voltage of each of the other SiC MOSFETs, to avoid overload at a time of subsequently switching on the SiC MOSFETs.

14. The method as recited in claim 13 further comprising:
establishing the respective negative switch-off voltage for each respective SiC MOSFET of the SiC MOSFETs depending on a threshold voltage of the respective SiC MOSFET.

15. The method as recited in claim 14, further comprising:
establishing the respective negative switch-off voltage for each respective SiC MOSFET such that a decreasing switch-off voltage is allocated to the respective SiC MOSFETs in an order of their increasing threshold voltage.

16. The method as recited in claim 11, further comprising:
electrically symmetrical switching on the SiC MOSFETs.

17. The method as recited in claim 11, wherein operation of the SiC MOSFET arrangement is performed by a switch unit.

18. A device, comprising:
a silicon carbide (SiC) MOSFET arrangement that includes two or more SiC MOSFETs which are connected electrically in parallel with one another, and a switch unit configured to switch the SiC MOSFET arrangement, wherein the switch unit is configured to switching on the SiC MOSFETs while avoiding overloading individual ones of the SiC MOSFETs.

19. The device as recited in claim 18, wherein the switch unit is configured to switch off each of the SiC MOSFETs at a respective established negative switch-off voltage that differs from a respective established negative switch-off voltage of each of the other SiC MOSFETs, to avoid overload at a time of subsequently switching on the SiC MOSFETs.

20. The device as recited in claim 18, wherein the switch unit is configured to switch the SiC MOSFETs on electrically symmetrically.
